(19) United States
(12) Patent Application Publication
(10) Pub. No.: US 2024/0357796 A1
(43) Pub. Date: Oct. 24, 2024

(54) SEMICONDUCTOR MEMORY DEVICES

(71) Applicant: Samsung Electronics Co., Ltd., Suwon-si (KR)

(72) Inventors: Han Jin Lim, Suwon-si (KR); Jin Woo Han, Suwon-si (KR); Ki Seok Lee, Suwon-si (KR)

(21) Appl. No.: 18/543,261

(22) Filed: Dec. 18, 2023

(30) Foreign Application Priority Data
Apr. 20, 2023 (KR) 10-2023-0051817

(51) Int. Cl. H10B 12/00; H10B 53/30

(52) U.S. Cl. CPC H10B 12/377; H01L 28/55; H10B 12/36; H10B 12/50; H10B 53/30

(57) ABSTRACT

Provided is a semiconductor memory device. The semiconductor memory device includes a substrate, a channel region on the substrate, first and second source/drain regions electrically connected to the channel region, a gate electrode that extends in a first direction and is on the channel region, a conductive line that extends in a second direction intersecting the first direction and is electrically connected to the second source/drain region, and a capacitor structure electrically connected to the first source/drain region on the substrate. The capacitor structure may include a plurality of first electrodes stacked and spaced apart from each other in a third direction perpendicular to an upper surface of the substrate, a plurality of trenches extending into the plurality of first electrodes, a capacitor dielectric film that extends along side walls of each of the plurality of trenches, and a plurality of second electrodes in the plurality of trenches, respectively.

### CROSS-REFERENCE TO RELATED APPLICATION

This application claims priority from Korean Patent Application No. 10-2023-0051817 filed on Apr. 20, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices.

In the case of conventional two-dimensional or planar semiconductor elements, the degree of integration is determined mainly by an area occupied by a unit memory cell, and therefore is greatly affected by the level of fine pattern formation technology. However, since extremely expensive apparatuses are required for miniaturization of patterns, the degree of integration of the two-dimensional semiconductor elements is increasing, but is still limited. Accordingly, three-dimensional semiconductor memory elements including memory cells arranged three-dimensionally have been proposed.

### SUMMARY

Aspects of the present disclosure provide semiconductor memory devices having improved reliability.

However, aspects of the present disclosure are not restricted to the one set forth above. The above and other aspects of the present disclosure will become more apparent to one of ordinary skill in the art to which the present disclosure pertains by referencing the detailed description of the present disclosure given below.

According to aspects of the present disclosure, there is provided a semiconductor memory device including a substrate, a channel region on the substrate, first and second source/drain regions electrically connected to the channel region, a gate electrode that extends in a first direction and is on the channel region, a conductive line that extends in a second direction intersecting the first direction and is electrically connected to the second source/drain region, and a capacitor structure electrically connected to the first source/drain region on the substrate. The capacitor structure may include a plurality of first electrodes stacked and spaced apart from each other in a third direction perpendicular to an upper surface of the substrate, a plurality of trenches that extend into the plurality of first electrodes, a capacitor dielectric film that extends along side walls of each of the plurality of trenches, and a plurality of second electrodes in the plurality of trenches, respectively.

According to aspects of the present disclosure, there is provided a semiconductor memory device including a substrate including a first region and a second region, a plurality of transistors that are on the first region of the substrate, ones of the plurality of transistors may each include a gate electrode, a channel region, and a source/drain region, and a capacitor structure electrically connected to the source/drain region of each of the ones of the plurality of transistors. The capacitor structure may include a plurality of first electrodes that extend in a first direction, are stacked and spaced apart from each other in a third direction perpendicular to an upper surface of the substrate, and have a stepped profile on the second region of the substrate, a plurality of second electrodes that extend in a second direction intersecting the first direction on the first region of the substrate, extend into the plurality of first electrodes, and are electrically connected to the source/drain region of each of the ones of the plurality of transistors, respectively, and a capacitor dielectric film between respective ones of the plurality of first electrodes and respective ones of the plurality of second electrodes.

According to aspects of the present disclosure, there is provided a semiconductor memory device including a peripheral circuit structure including a peripheral circuit element, and a cell structure that includes a plurality of memory cells and overlaps the peripheral circuit structure in a first direction. The peripheral circuit element may be configured to control an operation of at least one of the plurality of memory cells. Each of the plurality of memory cells may include a transistor and at least two capacitors electrically connected to the transistor. Each of the at least two capacitors may include a first electrode extending in a second direction that intersects the first direction, a second electrode that extends into the first electrode and is electrically connected to a source/drain region of the transistor, and a capacitor dielectric film including a ferroelectric material between the first electrode and the second electrode.

### BRIEF DESCRIPTION OF THE DRAWINGS

The above and other aspects and features of the present disclosure will become more apparent by describing in detail example embodiments thereof with reference to the attached drawings, in which:

FIG. 1 is an example circuit diagram for explaining a semiconductor memory device according to some embodiments.

FIG. 2 is an example plan view for explaining the semiconductor memory device according to some embodiments.

FIG. 3 is a cross-sectional view taken along line A-A′ of FIG. 2.

FIG. 4 is a cross-sectional view taken along line B-B′ of FIG. 2.

FIGS. 5 to 9 are example diagrams for explaining the selection structure of FIG. 3.

FIGS. 10 and 11 are example plan views for explaining the semiconductor memory device according to some embodiments.

FIGS. 12 and 13 are example cross-sectional views for explaining a semiconductor memory device according to some embodiments.

FIGS. 14 to 24 are cross-sectional views sequentially showing processes of fabricating the semiconductor memory device having the cross-section of FIG. 3.

### DETAILED DESCRIPTION

Although terms such as first and second are used to describe various elements or components in the present disclosure, it goes without saying that these elements or components are not limited by these terms. These terms are only used to distinguish a single element or component from other elements or components. Therefore, it goes without saying that a first element or component referred to below may be a second element or component within the technical idea of the present disclosure.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

Hereinafter, example embodiments according to the technical idea of the present disclosure will be described with reference to the accompanying drawings.

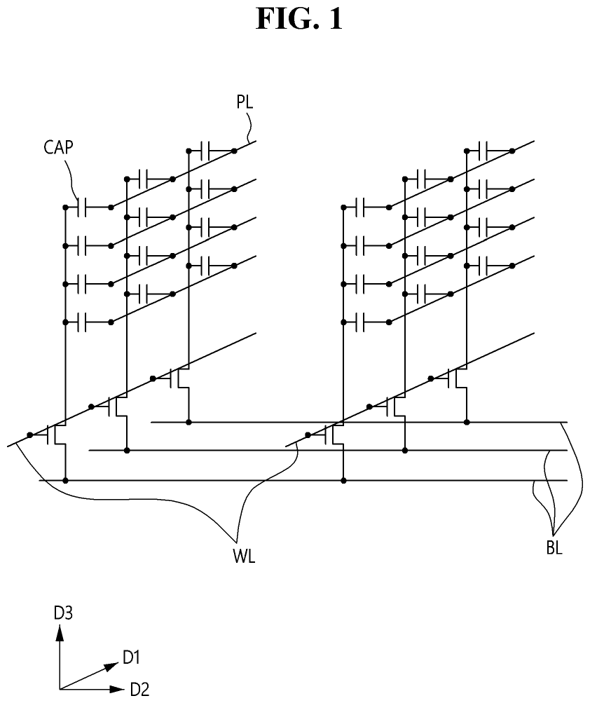

FIG. 1 is an example circuit diagram for explaining a semiconductor memory device according to some embodiments.

Referring to FIG. 1, the semiconductor memory device according to some embodiments may include word lines WL, bit lines BL, plate lines PL, and capacitors CAP.

The word lines WL may extend in a first direction D1. The plurality of word lines WL may be spaced apart from each other in a second direction D2. That is, the plurality of word lines WL may each extend in the first direction D1 and be spaced apart from each other in the second direction D2. Although two word lines WL are shown in FIG. 1, this is only for convenience of explanation, and the technical idea of the present disclosure is not limited thereto. As used herein, “an element A extends in a direction X” (or similar language) may mean that the element A extends longitudinally in the direction X. As used herein, the term “longitudinally” indicates a longest dimension.

In the present disclosure, the first direction D1 and the second direction D2 may intersect each other. The first direction D1 and the second direction D2 may be substantially perpendicular to each other. A third direction D3 may intersect the first direction D1 and the second direction D2. The first direction D1, the second direction D2 and the third direction D3 may be perpendicular to one another. In some embodiments, the word line WL may be a gate electrode of a transistor.

The bit lines BL may extend in the second direction D2. The bit lines BL may intersect the word lines WL. The bit lines BL may be connected to one end of the transistor. The other end of the transistor may be connected to the capacitor CAP.

In some embodiments, at least two capacitors CAP (i.e., two or more capacitors CAP) may be connected to one transistor. The semiconductor memory device according to some embodiments of the present disclosure may include a plurality of memory cells. Each of the plurality of memory cells may include one transistor and at least two or more capacitors. In the semiconductor memory device according to some embodiments, because at least two or more capacitors CAP are connected to one transistor, the product performance can be improved.

In some embodiments, the plate lines PL may be connected to one end of the capacitor CAP. The plate lines PL may be spaced apart from one another in the third direction D3. The plate lines PL may each extend in a direction parallel to the word lines WL, but are not limited thereto. In some embodiments, the plate lines PL and the word lines WL may be connected to each other, but the technical idea of the present disclosure is not limited thereto.

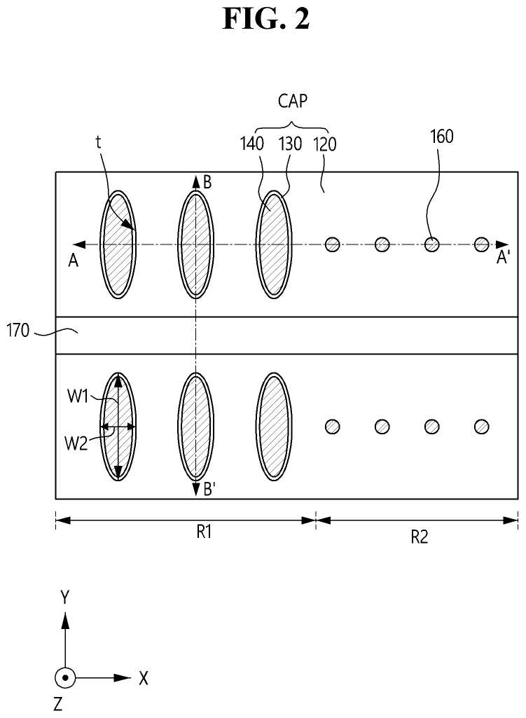

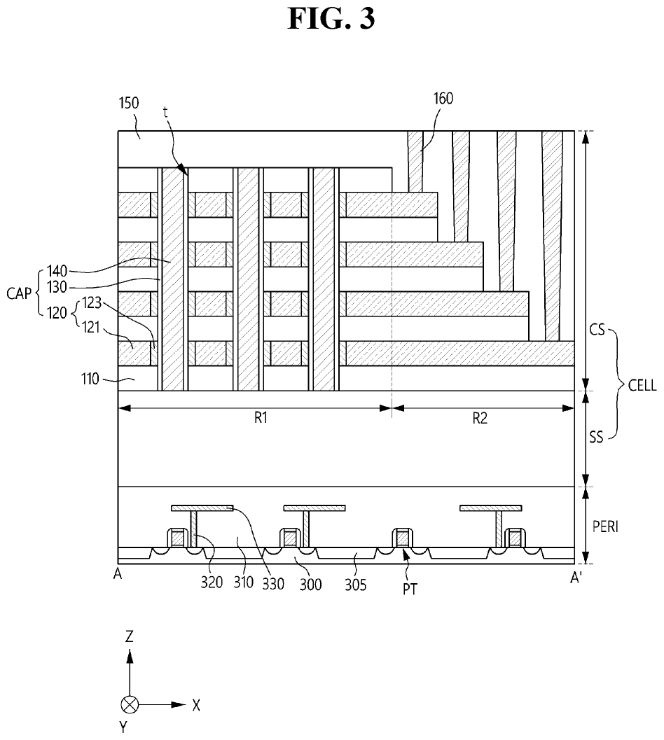

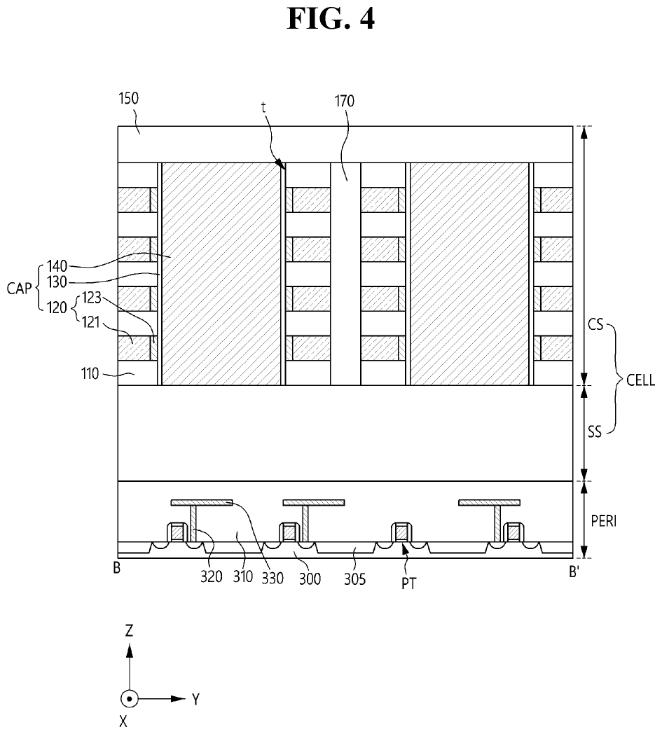

FIG. 2 is an example plan view for explaining the semiconductor memory device according to some embodiments. FIG. 3 is a cross-sectional view taken along line A-A′ of FIG. 2. FIG. 4 is a cross-sectional view taken along line B-B′ of FIG. 2.

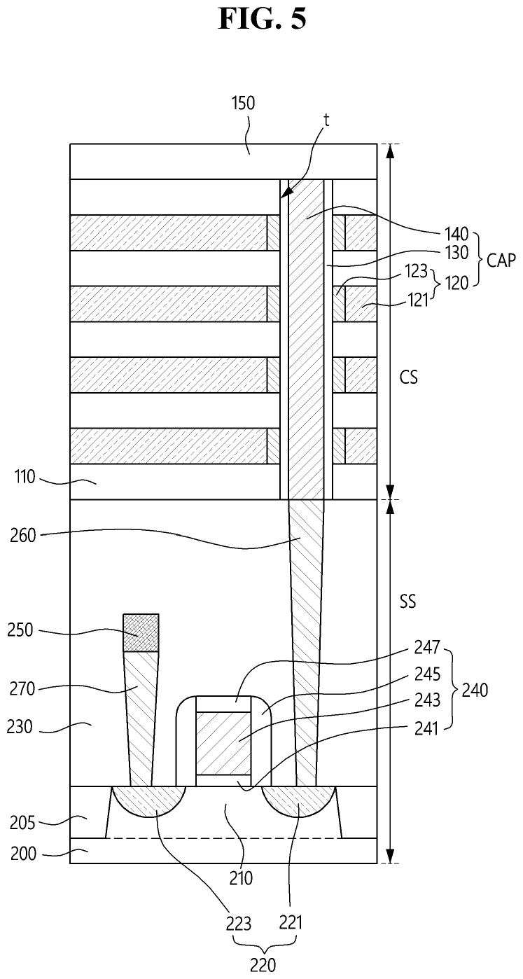

Referring to FIGS. 2 to 4, the semiconductor memory device according to some embodiments may include a peripheral circuit structure PERI and a cell structure CELL. The cell structure CELL may be placed on the peripheral circuit structure PERI. The cell structure CELL may overlap the peripheral circuit structure PERI in a z-direction Z. As used herein, “an element A overlaps an element B in a direction X” (or similar language) means that there is at least one line that extends in the direction X and intersects both the elements A and B. As an example, the z-direction Z may be a direction perpendicular to an upper side (i.e., upper surface) of a peripheral circuit board 300 (also referred to as a peripheral circuit substrate). As another example, the z-direction Z may be a direction perpendicular to the upper side (i.e., upper surface) of a substrate (e.g., 200 of FIG. 5).

In the present disclosure, the x-direction X, the y-direction Y, and the z-direction Z may intersect one another. The x-direction X, the y-direction Y, and the z-direction Z may be substantially perpendicular to one another.

The peripheral circuit structure PERI may include a peripheral circuit board 300 and a peripheral circuit element PT.

The peripheral circuit board 300 may include a semiconductor substrate such as, for example, a silicon substrate, a germanium substrate or a silicon-germanium substrate. As another example, the peripheral circuit board 300 may include a Silicon-On-Insulator (SOI) substrate or a Germanium-On-Insulator (GOI) substrate.

The peripheral circuit element PT may be formed on the peripheral circuit board 300. The peripheral circuit element PT may constitute a peripheral circuit that controls the operation of each memory cell of the semiconductor memory device. For example, the peripheral circuit element PT may include a control logic, a row decoder, a page buffer, and/or the like that controls an operation of at least one memory cell of the semiconductor memory device. In the following description, a surface of the peripheral circuit board 300 on which the peripheral circuit elements PT are placed may be referred to as a front side of the peripheral circuit board 300, and a surface of the peripheral circuit board 300 opposite to the front side of the peripheral circuit board 300 may be referred to as a back side of the peripheral circuit board 300.

The peripheral circuit element PT may include, for example, but is not limited to, a transistor. For example, the peripheral circuit element PT may include not only various active elements such as transistors, but also various passive elements such as a capacitor, a resistor and/or an inductor.

The peripheral circuit elements PT may be isolated by a peripheral element isolation film 305. For example, the peripheral element isolation film 305 may be provided inside the peripheral circuit board 300. The peripheral element isolation film 305 may be a shallow trench isolation (STI) film. The peripheral element isolation film 305 may define an active region of the peripheral circuit elements PT. The peripheral element isolation film 305 may include an insulating material. The peripheral element isolation film 305 may include, for example, at least one of silicon nitride, silicon oxide, or silicon oxynitride.

The peripheral circuit structure PERI may further include a plurality of wiring patterns 330, a plurality of wiring contacts 320 and a peripheral interlayer insulating film 310.

The peripheral interlayer insulating film 310 may be placed on the peripheral circuit board 300. The peripheral interlayer insulating film 310 may cover the peripheral circuit element PT.

A plurality of wiring patterns 330 and a plurality of wiring contacts 320 may be placed in the peripheral interlayer insulating film 310. The plurality of wiring patterns 330 and the plurality of wiring contacts 320 may be electrically connected to one another. The plurality of wiring patterns 330 and the plurality of wiring contacts 320 may electrically connect the peripheral circuit element PT and other components inside the cell structure CELL. Each of the plurality of wiring patterns 330 and the plurality of wiring contacts 320 may include a conductive material. For example, each of the plurality of wiring patterns 330 and the plurality of wiring contacts 320 may include, but are not limited to, tungsten (W) or copper (Cu).

A cell structure CELL may include a selection structure SS and a capacitor structure CS.

The selection structures SS may include word lines (e.g., WL of FIG. 1) and bit lines (e.g., BL of FIG. 1). The selection structure SS may be a region in which a transistor forming a memory cell is formed. A detailed explanation of the selection structure SS will be described later with reference to FIGS. 5 to 9.

The capacitor structure CS may include a plurality of capacitors CAP. The plurality of capacitors CAP may be stacked in the z-direction Z. Each of the plurality of capacitors CAP may include a first electrode 120, a second electrode 140, and a capacitor dielectric film 130. There may be two or more first electrodes 120. Although four first electrodes 120 are shown in FIGS. 3 and 4, this is only for convenience of explanation, and the technical idea of the present disclosure is not limited thereto.

In some embodiments, the capacitor structure CS may include a first region R1 and a second region R2.

Second electrodes 140 may be placed on the first region R1. The first electrodes 120 may be stacked on the second region R2 stepwise. Mold insulating films 110, which will be described below, may be stacked on the second region R2 stepwise. For example, the first electrodes 120 and the mold insulating films 110 may have a stepped profile on the second region R2. The first electrodes 120 and the mold insulating films 110 may have a layered structure extending in the x-direction X and the y-direction Y. The first electrodes 120 may be spaced apart from each other by the mold insulating film 110 and stacked in the z-direction Z. In some embodiments, the first electrodes 120 may extend in the x-direction X and the second electrodes 140 may extend in the y-direction Y.

The first electrodes 120 may extend in the x-direction X at different lengths and have a level difference. In some embodiments, the first electrodes 120 may have a level difference in the y-direction Y. For example, each of the first electrodes 120 may have a side surface that is not aligned with respective side surfaces of other ones of the first electrodes 120 in the z-direction Z. In other words, the first electrodes 120 may have a stepped profile (e.g., in a cross-sectional view). Therefore, each first electrode 120 may be exposed from other ones of the first electrodes 120. The exposed region may refer to a region in which respective ones of the first electrodes 120 and respective ones of the plurality of first electrode contacts 160 are in contact with each other.

For example, the first electrode contacts 160 may land on the exposed region. The first electrode contacts 160 may land on the first electrode 120 located at the highest level in the z-direction Z. The first electrode contacts 160 may pass through an upper interlayer insulating film 150, which will be described below. Each of the first electrode contacts 160 may be connected to one of the plurality of first electrodes 120. A voltage may be applied to the plurality of first electrodes 120 through the first electrode contacts 160. The upper face of each of the first electrode contacts 160 may all be placed on the same plane (i.e., may be coplanar). However, the technical idea of the present disclosure is not limited thereto.

The first electrode contacts 160 may include a conductive material. For example, the first electrode contacts 160 may include, but are not limited to, tungsten (W) or copper (Cu).

The mold insulating films 110 may be stacked in the second region R2 stepwise. For example, the mold insulating films 110 may extend in the x-direction X at different lengths and have a level difference. In some embodiments, the mold insulating films 110 may have a step difference in the y-direction Y. For example, each of the mold insulating films 110 may have a side surface that is not aligned with respective side surfaces of other ones of the mold insulating films 110 in the z-direction Z. In other words, the mold insulating films 110 may have a stepped profile (e.g., in a cross-sectional view).

In some embodiments, the first electrodes 120 may extend in the x-direction X. Although not shown, from a viewpoint of the plan view, the first electrodes 120 may include a first side extending in the x-direction X, and a second side extending in the y-direction Y. The length of the first side may be greater than the length of the second side. The first electrodes 120 may be stacked in the z-direction Z with each other.

In some embodiments, the capacitor structure CS may include a plurality of trenches t. Each of the plurality of trenches t may pass through the first electrodes 120 and the mold insulating films 110 in the z-direction Z. Each of the plurality of trenches t may expose a capacitor contact (e.g., 260 of FIG. 5) inside the selection structure SS.

The capacitor dielectric film 130 may be placed along side walls of the plurality of trenches t. The capacitor dielectric film 130 may be conformally placed on the side walls of the plurality of trenches t. The capacitor dielectric film 130 may not extend on the bottom faces of the trenches t. A part of the capacitor dielectric film 130 may be in contact with the first electrode 120. Another part of the capacitor dielectric film 130 may be in contact with the mold insulating film 110. For example, the capacitor dielectric film 130 may be between respective ones of the first electrodes 120 and respective ones of the second electrodes 140.

The second electrodes 140 may be interposed between the capacitor dielectric films 130. The second electrodes 140 may fill the plurality of trenches t. The second electrodes 140 may fill the remaining trench t on which the capacitor dielectric film 130 is placed. Each of the second electrodes 140 may be connected to a capacitor contact (e.g., 260 of FIGS. 5 to 9) of the selection structure SS. Each of the second electrodes 140 may be connected to a source/drain region (e.g., 221 of FIGS. 5 to 9) of the selection structure SS.

In some embodiments, the first electrodes 120 may each include a first sub-film 121 and a second sub-film 123. The second sub-film 123 may be in contact with the capacitor dielectric film 130. The first sub-film 121 may not be in contact with the capacitor dielectric film 130. For example, the first sub-film 121 may be spaced apart from the capacitor dielectric film 130 with the second sub-film 123 therebetween. The first sub-film 121 may be in contact with the first electrode contacts 160. The first sub-film 121 may be formed of a material having a lower resistance than the second sub-film 123. For example, the first sub-film 121 may include a polysilicon film and/or copper (Cu), but the technical idea of the present disclosure is not limited thereto.

The second sub-films 123 may each include, but are not limited to, a doped semiconductor material, a conductive metal nitride (e.g., titanium nitride, tantalum nitride, niobium nitride or tungsten nitride, etc.), a metal (e.g., ruthenium, iridium, titanium or tantalum, etc.), a conductive metal oxide (e.g., iridium oxide or niobium oxide), and/or the like.

In some embodiments, the capacitor dielectric film 130 may include a ferroelectric material film, a paraelectric material film, an antiferroelectric material film, and/or combinations thereof. For example, when the capacitor CAP has non-volatile memory properties, the capacitor dielectric film 130 may include one of a ferroelectric material film, a combined film of the ferroelectric material film and the antiferroelectric material film, and/or a combined film of the ferroelectric material film and the paraelectric material film. For example, when the capacitor CAP has volatile memory properties, the capacitor dielectric film 130 may include one of a paraelectric material film, a combined film of the ferroelectric material film and the antiferroelectric material film, and/or a combined film of the ferroelectric material film and paraelectric material film. However, the technical idea of the present disclosure is not limited thereto.

In some embodiments, the ferroelectric material film may include, for example, perovskite-series materials (i.e., perovskite materials) and/or fluorite-series materials (i.e., fluorite materials).

The ferroelectric material film may include hafnium (Hf)-zirconium (Zr) oxide. The antiferroelectric material film may include zirconium oxide, hafnium-zirconium oxide, lead-zirconium oxide (PbZrO₃), and/or sodium-niobium oxide (NaNbO₃). The ferroelectric material film and the antiferroelectric material film may include hafnium (Hf)-series materials. The ferroelectric material film and the antiferroelectric material film may include a material in which the hafnium (Hf)-zirconium (Zr) oxide is doped with doping elements such as aluminum (Al), barium (Ba), silicon (Si), yttrium (Y), scandium (Sc), and/or strontium (Sr). The ferroelectric material film and the antiferroelectric material film may include a lanthanum (La)-series rare earth element.

The paraelectric material film may include high dielectric constant materials such as beryllium oxide (BeO₂), magnesium oxide (MaO₂), calcium oxide (CaO₂), strontium oxide (SrO₂), aluminum oxide (Al₂O₃), yttrium oxide (Y₂O₃), scandium oxide (Sc₂O₃), lanthanum oxide (La₂O₃), hafnium oxide (HfO₂), zirconium oxide (ZrO₂), titanium oxide (TiO₂), tantalum oxide (Ta₂O₅), niobium oxide (Nb₂O₅), vanadium oxide (V₂O₅), strontium-titanium oxide (SrTiO₃), and/or barium-strontium-titanium oxide (BaSrTiO₃). However, the technical idea of the present disclosure is not limited thereto.

The second electrodes 140 may each include, for example, but are not limited to, a doped semiconductor material, a conductive metal nitride (e.g., titanium nitride, tantalum nitride, niobium nitride or tungsten nitride, etc.), a metal (e.g., ruthenium, iridium, titanium or tantalum, etc.), a conductive metal oxide (e.g., iridium oxide or niobium oxide), and/or the like.

The mold insulating films 110 may each include an insulating material. For example, the mold insulating films 110 may each include, but are not limited to, at least one of silicon oxide, silicon nitride, or silicon oxynitride. As an example, the mold insulating film 110 may include silicon oxide.

The capacitor structure CS may further include an upper interlayer insulating film 150. The upper interlayer insulating film 150 may cover the mold insulating films 110, the first electrodes 120, the capacitor dielectric film 130 and the second electrodes 140. The upper interlayer insulating film 150 may include an oxide-series insulating material. The upper interlayer insulating film 150 may include, for example, but is not limited to, at least one of silicon oxide, silicon oxynitride, or a low-k material having a lower dielectric constant than silicon oxide.

In some embodiments, the capacitor structure CS may further include an electrode cutting structure 170. The electrode cutting structure 170 may cut the first electrodes 120. The electrode cutting structure 170 may cut the mold insulating films 110. Although not shown, two adjacent electrode cutting structures 170 may define one capacitor block between them. A plurality of second electrodes 140 may be placed inside the capacitor block defined by the electrode cutting structure 170. For example, the electrode cutting structure 170 may extend into the first electrodes 120 between respective ones of the second electrodes 140, which are adjacent to each other in the y-direction Y.

In FIG. 2, the electrode cutting structure 170 may extend in the x-direction X. However, the technical idea of the present disclosure is not limited thereto.

The upper face of the electrode cutting structure 170 may be coplanar with the upper face of the second electrode 140. The upper face of the electrode cutting structure 170 may be coplanar with the upper faces of the trenches t. The electrode cutting structure 170 may include an insulating material. For example, the insulating material may fill the electrode cutting structure 170. The insulating material may include, for example, but is not limited to, at least one of silicon oxide, silicon nitride, or silicon oxynitride.

In some embodiments, each of the trenches t may extend in the y-direction Y from a viewpoint of the plan view. For example, the shape of each of the trenches t may be an elliptical shape from a viewpoint of the plan view. Each trench t may include a first width W1 in the y-direction Y and a second width W2 in the x-direction X. The first width W1 may be a major axis of the ellipse, and the second width W2 may be a minor axis of the ellipse. The first width WI may be greater than the second width W2. However, the technical idea of the present disclosure is not limited thereto. Similarly, the shape of each of the second electrodes 140 may be an elliptical shape from a viewpoint of the plan view. The elliptical shape of each of the second electrodes 140 may extend longitudinally in the y-direction Y.

In the semiconductor memory device according to some embodiments, one capacitor CAP may include one first electrode 120. Therefore, different voltages may be applied to each of the plurality of first electrodes 120, when storing data using the semiconductor memory device. Accordingly, the performance and reliability of the semiconductor memory device can be improved, and efficiency of the cell area can be improved.

The selection structure will be described in more detail below with reference to FIGS. 5 to 9. FIGS. 5 to 9 are example diagrams for explaining the selection structure of FIG. 3.

Referring to FIGS. 5 to 9, a transistor may be placed inside the selection structure SS. The transistor may be connected to the capacitor CAP of the capacitor structure CS. The transistor may include at least one of a buried transistor (BCAT), a planar transistor, a fin-shaped transistor (FinFET), a multi-bridge channel transistor (MBCFET), and/or a vertical channel transistor (VCT).

Referring to FIG. 5, the transistor may be a planar transistor.

The selection structure SS may include a substrate 200, an element isolation film 205, a channel region 210, a source/drain region 220, a gate structure 240, a conductive line 250, a capacitor contact 260, a bit line contact 270, and a lower interlayer insulating film 230.

The substrate 200 may be provided. The substrate 200 may be, for example, a silicon single crystal substrate or a SOI (Silicon on Insulator) substrate. As another example, the substrate 200 may include, but is not limited to, silicon germanium, silicon germanium on insulator (SGOI), indium antimonide, lead telluride, indium arsenide, indium phosphide, gallium arsenide or gallium antimonide.

In some embodiments, the substrate 200 may include a first region R1 and a second region R2 (e.g., see FIGS. 2 and 3). The first region R1 may be a region in which the plurality of second electrodes 140 are placed. The first region R1 may be a region in which a transistor connected to the second electrode 140 is formed.

The element isolation film 205 may be placed inside the substrate 200. The element isolation film 205 may define the channel region 210 and the source/drain region 220 between adjacent transistors. The element isolation film 205 may be a shallow trench isolation (STI) film. The element isolation film 205 may include an insulating material. The element isolation film 205 may include, for example, at least one of silicon nitride, silicon oxide, or silicon oxynitride.

The channel region 210 and the source/drain region 220 may be placed inside the substrate 200. The channel region 210 may be placed between the source/drain regions 220. The channel region 210 may be a channel of a transistor, and the source/drain region 220 may be a source and a drain of the transistor.

As an example, the channel region 210 may include a single crystal silicon film. As another example, the channel region 210 may include a polysilicon film. As still another example, the channel region 210 may include IGZO (Indium Gallium Zinc Oxide).

The source/drain regions 220 may be formed by doping the substrate 200 with N-type impurities or P-type impurities. For example, if the transistor is an N-type metal-oxide-semiconductor (NMOS), the source/drain region 220 may be doped with N-type impurities. If the transistor is a P-type metal-oxide-semiconductor (PMOS), the source/drain region 220 may be doped with P-type impurities.

A gate structure 240 may be placed on the substrate 200. The gate structure 240 may include a gate insulating film 241, a gate electrode 243, a gate spacer 245, and a gate capping film 247.

The gate electrode 243 may be placed on the substrate 200. The gate electrode 243 may be a gate of a transistor. The gate electrode 243 may extend alongside the first electrode 120 of the capacitor structure CS. For example, in some embodiments, the gate electrode 243 and the first electrode 120 may extend in the same direction. The gate electrode 243 may be a word line (e.g., WL of FIG. 1) of the semiconductor memory device. The gate electrode 243 may be placed between the source/drain regions 220. The gate electrode 243 may be placed on the channel region 210.

The gate electrode 243 may include a conductive material. As an example, the gate electrode 243 may include, but is not limited to, at least one of a doped semiconductor material (doped silicon, doped silicon-germanium, doped germanium, etc.), a conductive metal nitride (titanium nitride, tantalum nitride, etc.), a metal (tungsten, titanium, tantalum, etc.), or metal-semiconductor compounds (tungsten silicide, cobalt silicide, titanium silicide, etc.).

The gate electrode 243 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof.

The gate insulating film 241 may be placed between the gate electrode 243 and the channel region 210. Although the gate insulating film 241 is shown as being placed only between the lower face of the gate electrode 243 and the upper face of the channel region 210, the technical idea of the present disclosure is not limited thereto. The gate insulating film 241 may include at least one of a high dielectric constant insulating film, a silicon oxide film, a silicon nitride film, or a silicon oxynitride film. As an example, the high dielectric constant insulating film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate capping film 247 may be placed on the gate electrode 243. The gate capping film 247 may include, for example, at least one of silicon nitride (SiN), silicon oxynitride (SiON), silicon oxide (SiO₂), silicon carbonitride (SiCN), silicon oxycarbonitride (SiOCN), or combinations thereof.

The gate spacer 245 may be placed on side walls of the gate electrode 243 and side walls of the gate capping film 247. The gate spacer 245 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), or combinations thereof.

In some embodiments, the transistor placed inside the selection structure SS may include a gate electrode 243, a channel region 210, and a source/drain region 220. Although FIG. 5 shows that only one transistor is placed in the selection structure SS, this is only for convenience of explanation, and the selection structure SS may include more than one transistor. Needless to say, at least two transistors may be placed in the selection structure SS.

The conductive line 250 may be placed on the substrate 200. The conductive line 250 may be a bit line (e.g., BL of FIG. 1) of a semiconductor memory device. The conductive line 250 may extend in a direction that intersects the gate electrode 243. For example, the conductive line 250 and the gate electrode 243 may extend in directions perpendicular to each other, but are not limited thereto.

The conductive line 250 may include a conductive material. For example, the conductive line 250 may be formed of tungsten (W) or copper (Cu). As another example, the conductive line 250 may be formed of multiple films. However, the technical idea of the present disclosure is not limited thereto.

In some embodiments, the source/drain region 220 may include a first source/drain region 221 and a second source/drain region 223. The first source/drain region 221 may be connected to the capacitor CAP. The second source/drain region 223 may be connected to the bit line. That is, the second source/drain region 223 may be connected to the conductive line 250. The first and second source/drain regions 221 and 223 may be electrically connected to opposing side surfaces of the channel region 210, respectively.

The capacitor contact 260 may be placed between the second electrode 140 and the first source/drain region 221. The capacitor contact 260 may electrically connect the second electrode 140 and the first source/drain region 221. The capacitor contact 260 may include a conductive material. The capacitor contact 260 may be formed of tungsten (W) or copper (Cu). The capacitor contact 260 may be formed of multiple films, unlike the shown example. If the capacitor contact 260 is formed of multiple films, the capacitor contact 260 may include a barrier film and a filling film. The barrier film may be formed of a titanium nitride (TiN) film, and the filling film may be formed of a tungsten (W) film.

The bit line contact 270 may be placed between the conductive line 250 and the second source/drain region 223. The bit line contact 270 may electrically connect the conductive line 250 and the second source/drain region 223. The bit line contact 270 may include a conductive material. The bit line contact 270 may be formed of tungsten (W) or copper (Cu). The bit line contact 270 may be formed of multiple films, unlike the shown example. If the bit line contact 270 is formed of multiple films, the bit line contact 270 may include a barrier film and a filling film. The barrier film may be formed of a titanium nitride (TiN) film, and the filling film may be formed of a tungsten (W) film.

The lower interlayer insulating film 230 may be placed on the substrate 200. The lower interlayer insulating film 230 may cover the gate structure 240, the bit line contact 270, the capacitor contact 260 and the conductive line 250. The lower interlayer insulating film 230 may include an insulating material. For example, the lower interlayer insulating film 230 may be formed of, but is not limited to, a silicon oxide film.

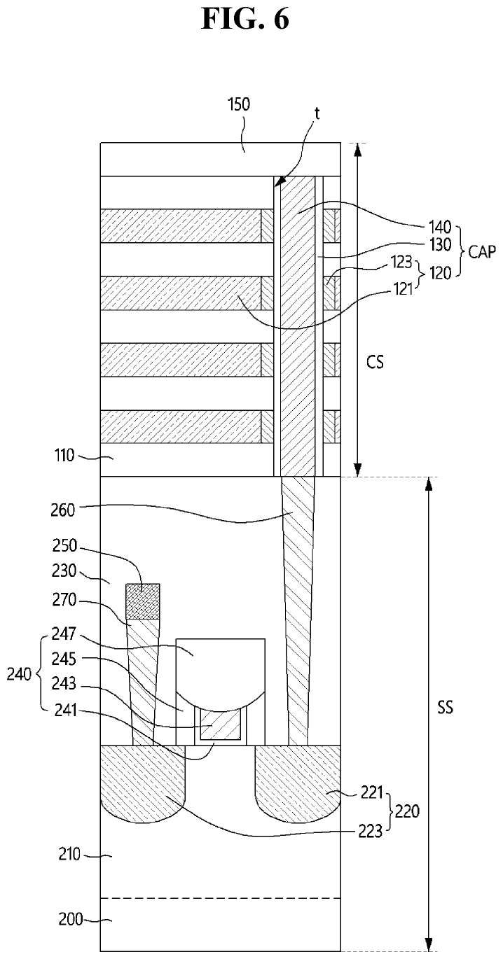

Referring to FIG. 6, the transistor may be a fin-shaped transistor (FinFET). The fin-shaped transistor may refer to a structure in which the channel region 210 protrudes from the substrate 200. For convenience of explanation, the repeated parts of contents explained above with reference to FIG. 5 will be briefly explained or omitted.

The channel region 210 may have a fin-like shape. That is, the channel region 210 may be placed on the substrate 200, and may protrude from the substrate 200. For example, the channel region 210 may protrude from the substrate 200 in a vertical direction. The portion of the channel region 210 placed between the source/drain regions 220 may function as the channel of the transistor. The channel region 210 may extend in a direction perpendicular to the gate electrode 243, but is not limited thereto.

In some embodiments, the gate structure 240 may be formed using a replacement process. For example, the gate spacer 245 may be formed first, and a dummy gate electrode may be formed between the gate spacers 245. After that, the dummy gate electrode is removed, and the gate insulating film 241 and the gate electrode 243 may be formed in a space from which the dummy gate electrode is removed.

The gate insulating film 241 may extend along the inner side walls of the gate spacers 245 and the upper face of the channel region 210. That is, the gate insulating film 241 may have a ‘U’ shape. The gate electrode 243 may be placed on the gate insulating film 241. The gate capping film 247 may be placed on the gate spacer 245 and the gate electrode 243. A bottom face of the gate capping film 247 may be a curved face that is recessed toward the gate electrode 243 (e.g., a convex face), but the technical idea of the present disclosure is not limited thereto.

Although not shown, the gate electrode 243 may wrap (i.e., surround) at least a part of the channel region 210. The gate electrode 243 may surround the channel region 210 between the source/drain regions 220. It will be understood that “an element A surrounds an element B” (or similar language) as used herein means that the element A is at least partially around the element B and/or that the element A is around the element B when viewed with respect to at least one plane, but does not necessarily mean that the element A completely encloses the element B.

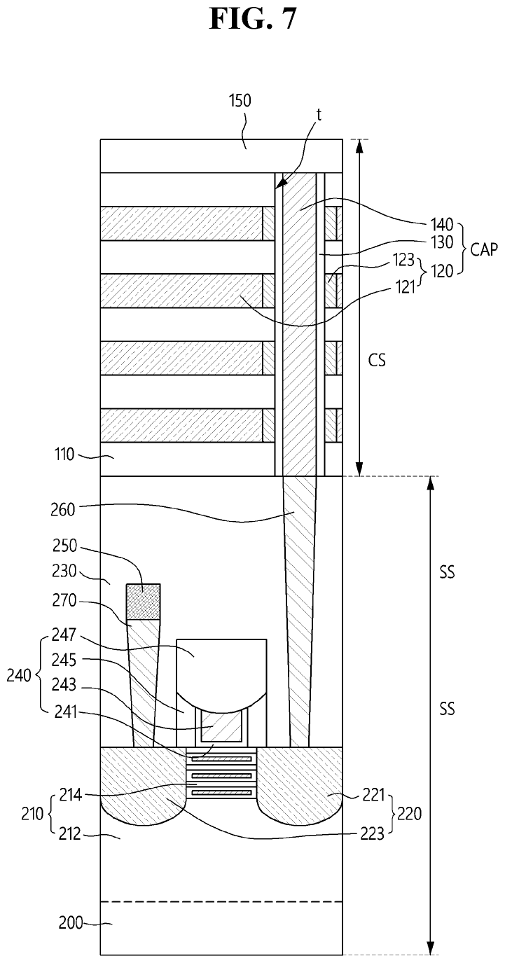

Referring to FIG. 7, the transistor may be a multi-bridge channel transistor (MBCFET). The multi-bridge channel transistor may refer to a structure in which the channel region includes a plurality of sheet patterns spaced apart from each other, and a gate electrode of the transistor wraps (i.e., surrounds) the sheet patterns. For convenience of explanation, the repeated parts of contents explained above with reference to FIGS. 5 and 6 will be briefly explained or omitted.

The channel region 210 may include a lower pattern 212 and a sheet pattern 214. The lower pattern 212 may be placed on the substrate 200. The lower pattern 212 may extend in a direction perpendicular to the gate electrode 243. The sheet pattern 214 may be placed on the lower pattern 212. At least two or more sheet patterns 214 may be placed. Although three sheet patterns 214 are shown, this is only for convenience of explanation, and the technical idea of the present disclosure is not limited thereto.

In some embodiments, the gate electrode 243 may wrap (i.e., surround) the periphery of the sheet pattern 214. For example, the gate electrode 243 may surround the sheet pattern 214 with opposing side surfaces of the sheet pattern 214 electrically connected to the source/drain regions 220, respectively. A part of the gate insulating film 241 may be interposed between the sheet pattern 214 and the gate electrode 243.

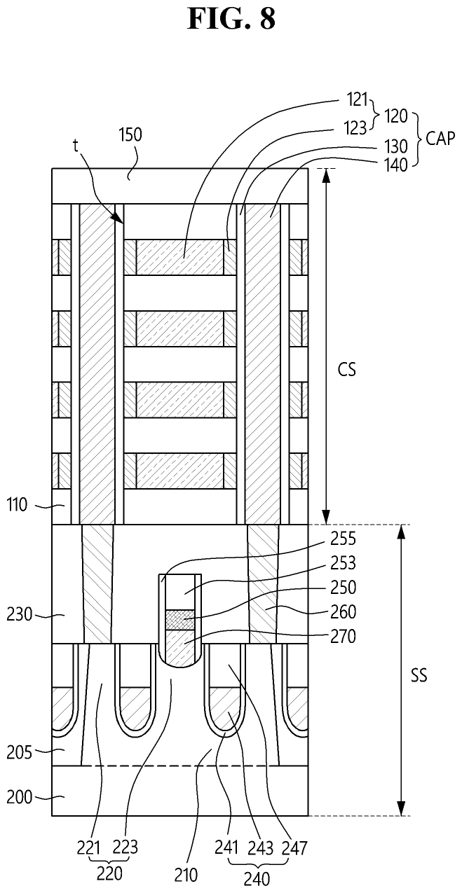

Referring to FIG. 8, the transistor may be a buried transistor (BCAT). The buried transistor (also referred to as a buried-channel-array transistor) may refer to a structure in which the gate electrode of the transistor is buried in the substrate 200. For convenience of explanation, the repeated parts of contents explained above with reference to FIG. 5 will be briefly explained or omitted.

The gate structure 240 may be buried inside the substrate 200. The gate structure 240 includes a gate insulating film 241, a gate electrode 243 and a gate capping film 247. A gate trench may be formed in the substrate 200. The gate insulating film 241 may be placed along side walls of the gate trench. The gate electrode 243 may partially fill the gate trench. That is, the gate electrode 243 may be buried inside the substrate 200. The gate capping film 247 may fill the remaining part of the gate trench. The upper face of the gate capping film 247 may be coplanar with the upper side of the substrate 200.

An impurity doping region may be formed on one side and the other side of the gate structure 240. The impurity doping region may be the source/drain region 220 of the transistor. If the transistor is an NMOS, the source/drain region 220 may include N-type impurities. If the transistor is a PMOS, the source/drain region 220 may include P-type impurities.

The channel region 210 may be placed between the source/drain regions 220. The channel region 210 may be placed along the profile of the gate structure 240. However, the technical idea of the present disclosure is not limited thereto.

The semiconductor memory device according to some embodiments may further include a bit line spacer 255 and a bit line capping film 253.

The bit line capping film 253 may be placed on the conductive line 250. The bit line capping film 253 may extend along the upper face of the conductive line 250. The bit line capping film 253 may include, for example, at least one of a silicon nitride film, silicon oxynitride, silicon carbonitride, or silicon oxycarbonitride. As an example, the bit line capping film 253 may include the silicon nitride film. Although the bit line capping film 253 is shown as a single film, it is not limited thereto.

The bit line spacer 255 may be placed on the side walls of the conductive line 250 and the bit line capping film 253. The bit line spacer 255 may extend in the same direction as the conductive line 250 on the side walls of the conductive line 250 and the bit line capping film 253. The bit line spacer 255 may be a single film as shown, or may be multiple films unlike the shown example. The bit line spacer 255 may include, for example, but is not limited to, one of a silicon oxide film, a silicon nitride film, a silicon oxynitride film (SiON), a silicon oxycarbonitride film (SiOCN), air, or combinations thereof.

The bit line contact 270 may be placed between the conductive line 250 and the second source/drain region 223. The bit line contact 270 may be interposed between the bit line spacers 255. The bit line contact 270 may not horizontally overlap the gate electrode 243.

The bit line contact 270 may include, but is not limited to, at least one of a semiconductor material doped with impurities, a conductive silicide compound, a conductive metal nitride, or a metal.

In some embodiments, the conductive line 250 may be formed of multiple films. For example, although not shown, the conductive line 250 may include first to third conductive films. The first to third conductive films may be sequentially stacked on the substrate. The first conductive film may include a doped semiconductor material, the second conductive film may include at least one of a conductive silicide compound or a conductive metal nitride, and the third conductive film may include at least one of a metal or a metal alloy. However, the technical idea of the present disclosure is not limited thereto.

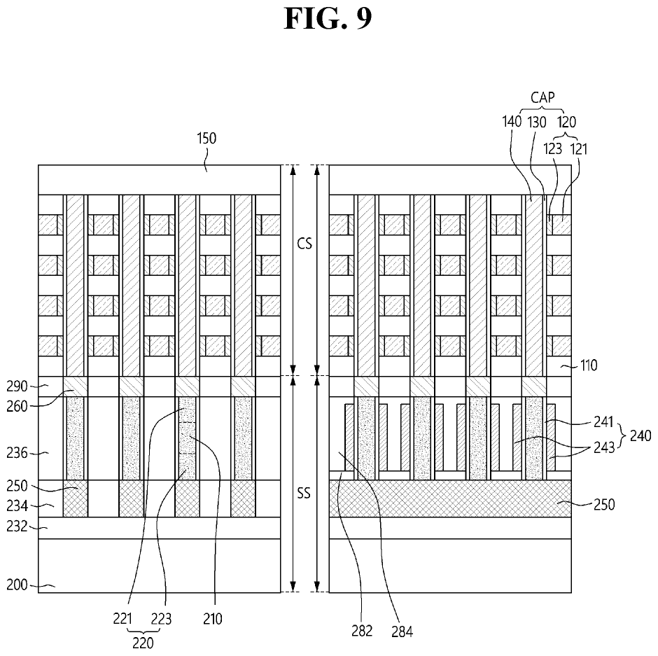

Referring to FIG. 9, the transistor may be a vertical channel transistor (VCT). The vertical channel transistor may refer to a structure in which the channel length of the channel region 210 extends from the substrate 200 along the vertical direction.

A lower insulating layer 232 may be placed on the substrate 200, and a plurality of conductive lines 250 may be placed on the lower insulating layer 232. The plurality of conductive lines 250 may be bit lines (e.g., BL of FIG. 1) of the semiconductor memory device. A plurality of first insulating patterns 234 may be placed on the lower insulating layer 232 to fill the space between the plurality of conductive lines 250. An upper face of the first insulating pattern 234 may be coplanar with the upper face of the conductive line 250.

The channel region 210 may be arranged on the conductive line 250 in a matrix form placed to be spaced apart in the horizontal direction. A horizontal width of the channel region 210 may be smaller than a vertical height of the channel region 210. The bottom portion of the channel region 210 may be connected to the second source/drain region 223. The second source/drain regions 223 may be connected to the conductive line 250. An upper part of the channel region 210 may be connected to the first source/drain region 221. The first source/drain regions 221 may be connected to the capacitor contact 260. The first source/drain region 221 may be connected to the capacitor CAP.

In some embodiments, the channel region 210 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}ZₙzO, InₓGa_{y}O or combinations thereof. The channel region 210 may include a single layer or multiple layers of the oxide semiconductor. In some embodiments, the channel region 210 may have a bandgap energy that is greater than the bandgap energy of silicon. For example, the channel region 210 may have a bandgap energy of about 1.5 eV to 5.6 eV. For example, the channel region 210 may have optimum channel performance when having the bandgap energy of about 2.0 eV to 4.0 eV. For example, the channel region 210 may be, but is not limited to, polycrystalline or amorphous. In some embodiments, the channel region 210 may include a two-dimensional semiconductor material, and the two-dimensional semiconductor material may include, for example, graphene, carbon nanotube or a combination thereof.

The gate electrode 243 may be placed on both side walls of the channel region 210. The gate electrode 243 may be placed on one side and the other side of the channel region 210. As one channel region 210 is placed between the gate electrodes 243, the semiconductor memory device may have a dual gate transistor structure. However, the technical idea of the present disclosure is not limited thereto.

The gate insulating film 241 may surround the side walls of the channel region 210. The gate insulating film 241 may be interposed between the channel region 210 and the gate electrode 243. For example, as shown in FIG. 9, all the side walls of the channel region 210 may be surrounded by the gate insulating film 241, and a part of the side walls of the gate electrode 243 may be in contact with the gate insulating film 241. In some embodiments, the gate insulating film 241 may extend in the extending direction of the gate electrode 243, and only two side walls of the channel region 210 facing the gate electrode 243 may come into contact with the gate insulating film 241.

Second insulating patterns 236 may be placed on the first insulating pattern 234. A first buried layer 282 and a second buried layer 284 may be placed in the space between two adjacent channel regions 210, between two adjacent second insulating patterns 236. The first buried layer 282 is placed at the bottom part of the space between two adjacent channel regions 210, and the second buried layer 284 may be formed to fill the rest of the space between two adjacent channel regions 210 above the first buried layer 282. The upper face of the second buried layer 284 may be placed at the same level as the upper face of the first source/drain region 221 (e.g., may be coplanar), and the second buried layer 284 may cover the upper face of the gate electrode 243. In some embodiments, the plurality of second insulating patterns 236 may be formed of a material layer that is continuous with the plurality of first insulating patterns 234, or the second buried layer 284 may be a material layer that is continuous with the first buried layer 282.

The capacitor contact 260 may be placed on the first source/drain region 221. The capacitor contact 260 is placed to vertically overlap the channel region 210, and may be arranged in a matrix form. The capacitor contact 260 may include, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or a combination thereof. An upper insulating film 290 may surround side walls of the capacitor contact 260 on the plurality of second insulating patterns 236 and the second buried layer 284. The capacitor contact 260 and the second electrode 140 may be connected together.

The semiconductor memory device according to some embodiments will be described below.

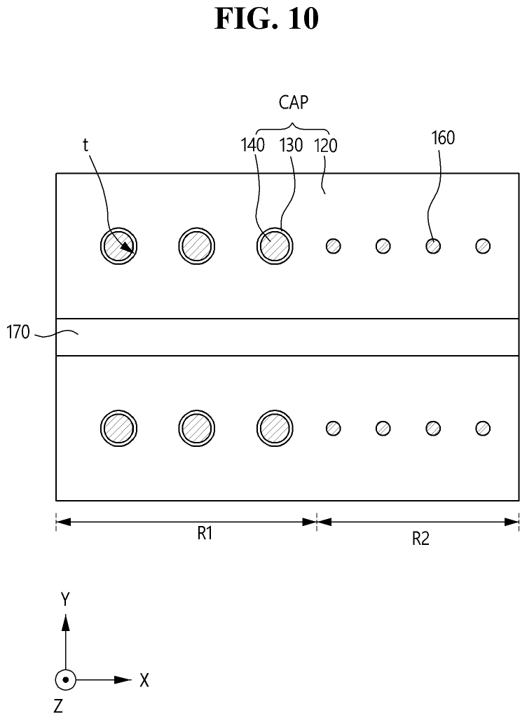

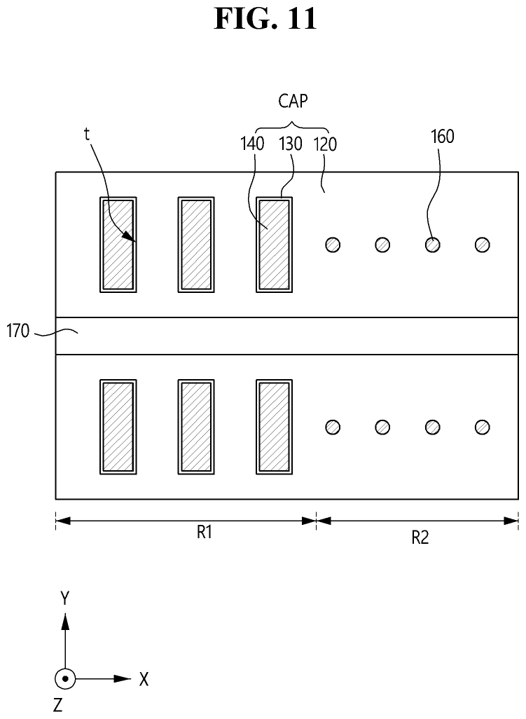

FIGS. 10 and 11 are example plan views for explaining the semiconductor memory device according to some embodiments.

Referring to FIG. 10, the shape of each trench t may be circular from a viewpoint of the plan view. That is, the width of the trench t in the x-direction X and the width of the trench t in the y-direction Y may be substantially the same. Similarly, the shape of each of the second electrodes 140 may be circular from a viewpoint of the plan view. The width in the x-direction X and the width in the y-direction Y of the second electrodes 140 may be substantially the same.

Referring to FIG. 11, the shape of each of the trenches t may be rectangular from a viewpoint of the plan view. That is, the width in the x-direction X and the width in the y-direction Y of the trenches t may be different from each other. The width of the trenches t in the x-direction X may be smaller than the width of the trenches t in the y-direction Y. That is, each of the trenches t may extend in the y-direction Y. Similarly, the shape of each of the second electrodes 140 may be rectangular from a viewpoint of the plan view. The width in the x-direction X and the width in the y-direction Y of the second electrodes 140 may be different from each other. The width of the second electrodes 140 in the x-direction X may be smaller than the width of the second electrodes 140 in the y-direction Y. That is, each of the second electrodes 140 may extend in the y-direction Y.

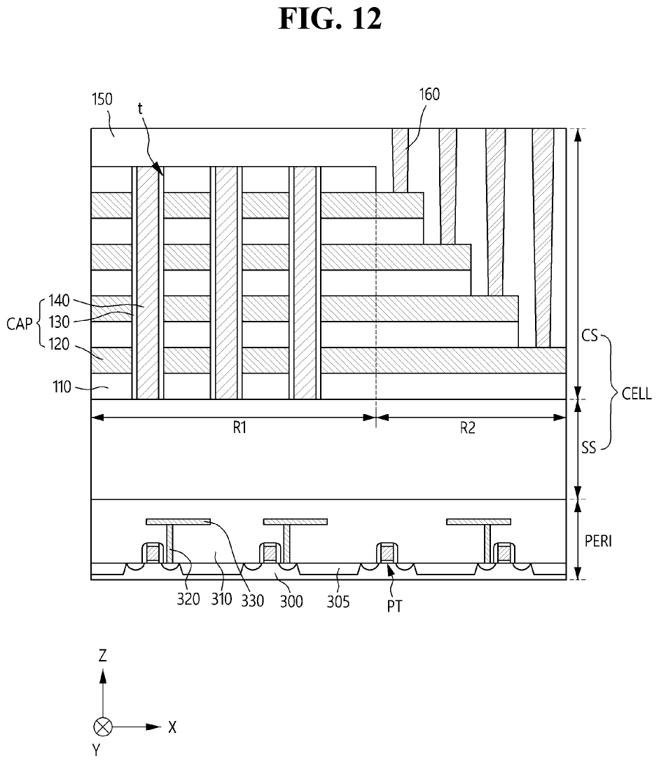

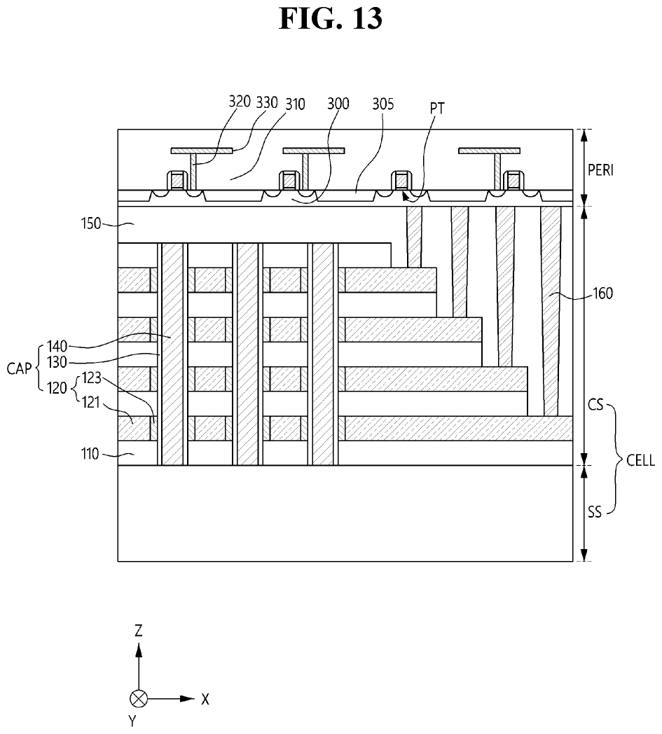

FIGS. 12 and 13 are example cross-sectional views for explaining a semiconductor memory device according to some embodiments. For convenience of explanation, the repeated parts of contents explained above with reference to FIG. 3 will be briefly explained or omitted.

Referring to FIG. 12, the first electrodes 120 may be formed of a single film. The first electrodes 120 do not include a portion that is not in contact with the capacitor dielectric film 130. That is, the first electrodes 120 may include a single film rather than multiple films. After the first electrodes 120 are formed, a dummy electrode may be completely removed and the removed region may be filled with the first electrode 120.

Referring to FIG. 13, the peripheral circuit structure PERI may be placed on the capacitor structure CS. The capacitor structure CS may be interposed between the peripheral circuit structure PERI and the selection structure SS.

A method for fabricating a semiconductor memory device according to some embodiments will be described below.

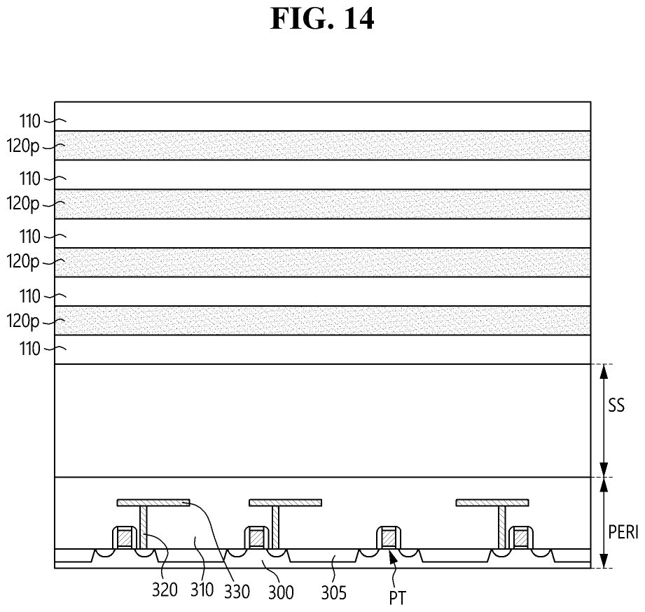

FIGS. 14 to 24 are cross-sectional views sequentially showing processes of fabricating the semiconductor memory device having the cross-section of FIG. 3.

Referring to FIG. 14, the peripheral circuit structure PERI may be formed. First, a peripheral circuit board 300 may be provided. A peripheral element isolation film 305 may be formed inside the peripheral circuit board 300. A peripheral circuit element PT, a plurality of wiring patterns 330, a plurality of wiring contacts 320, and a peripheral interlayer insulating film 310 may be formed on the peripheral circuit board 300.

The selection structure SS may be formed on the peripheral circuit structure PERI. The selection structure SS may include a plurality of transistors. Each of the plurality of transistors may include at least one of a buried transistor (BCAT), a planar transistor, a fin-shaped transistor (FinFET), a multi-bridge channel transistor (MBCFET), and/or a vertical channel transistor (VCT). The selection structure SS may be one of those described above with reference to FIGS. 5 to 9.

Subsequently, the mold insulating film 110 and a dummy first electrode 120p may be alternately stacked with one another on the selection structure SS. The mold insulating film 110 may be formed first. The dummy first electrode 120p may be formed on the mold insulating film 110. The mold insulating film 110 may be formed on the dummy first electrode 120p again.

The mold insulating film 110 and the dummy first electrode 120p may each have an etching selectivity. For example, the mold insulating film 110 may include an oxide-series insulating material, and the dummy first electrode 120p may include a nitride-series insulating material. As an example, the dummy first electrode 120p may include doped polysilicon, but the technical idea of the present disclosure is not limited thereto.

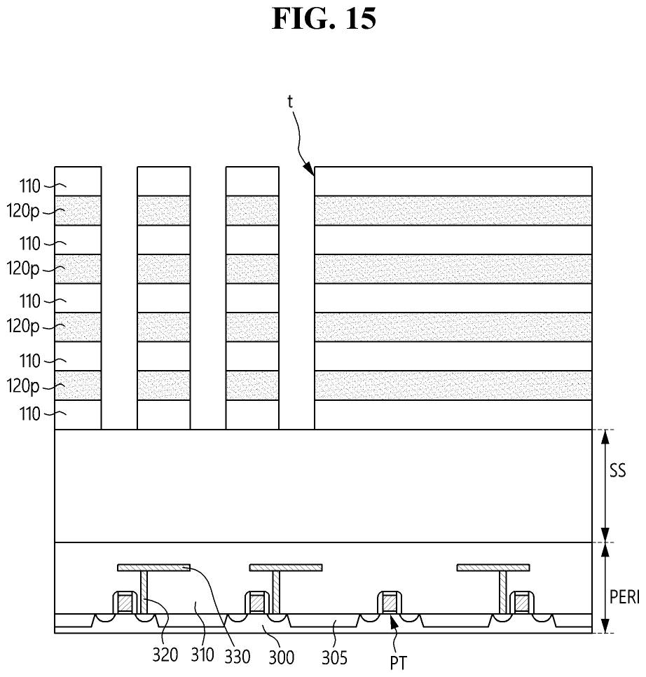

Referring to FIG. 15, a plurality of trenches t may be formed. The plurality of trenches t may penetrate (i.e., extend into) the mold insulating film 110 and the dummy first electrodes 120p. The plurality of trenches t may expose the selection structures SS. The plurality of trenches t may expose the capacitor contacts (e.g., 260 of FIGS. 5 to 9) of the selection structure SS.

In some embodiments, the shape of the plurality of trenches t may be elliptical from a viewpoint of the plan view. In some embodiments, the shape of the plurality of trenches t may be circular or rectangular from a viewpoint of the plan view.

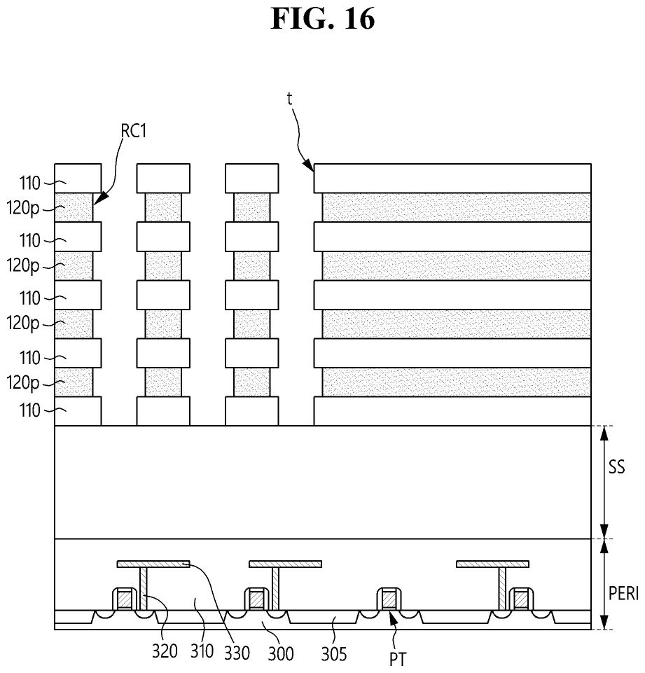

Referring to FIG. 16, a first recess RC1 may be formed. A part of the dummy first electrode 120p exposed by side walls of the plurality of trenches t may be removed. A part of the dummy first electrode 120p may be removed by a wet etching process. As described above, the dummy first electrode 120p and the mold insulating film 110 may have an etching selectivity. Therefore, only the dummy first electrode 120p may be selectively removed. The mold insulating film 110 may not be removed, while the dummy first electrode 120p is being removed.

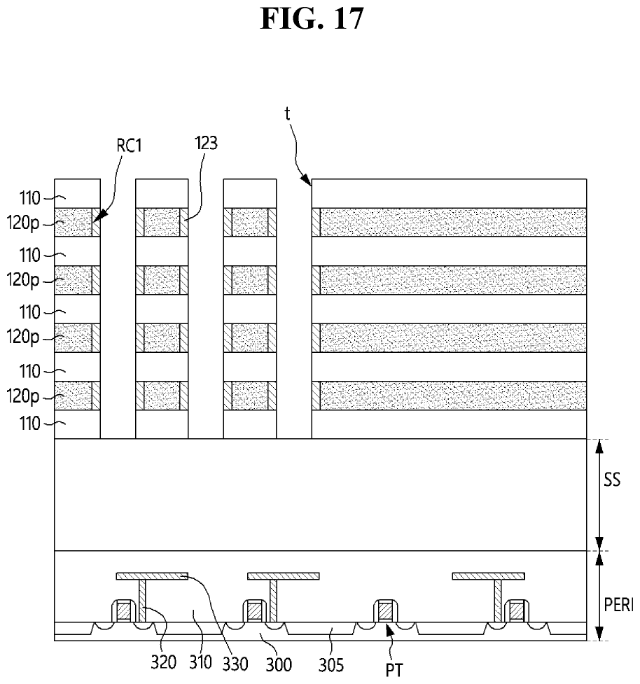

Referring to FIG. 17, a second sub-film 123 may be formed inside the first recess RC1. Although the side walls of the second sub-film 123 are shown as being coplanar with the side walls of the mold insulating film 110, the technical idea of the present disclosure is not limited thereto.

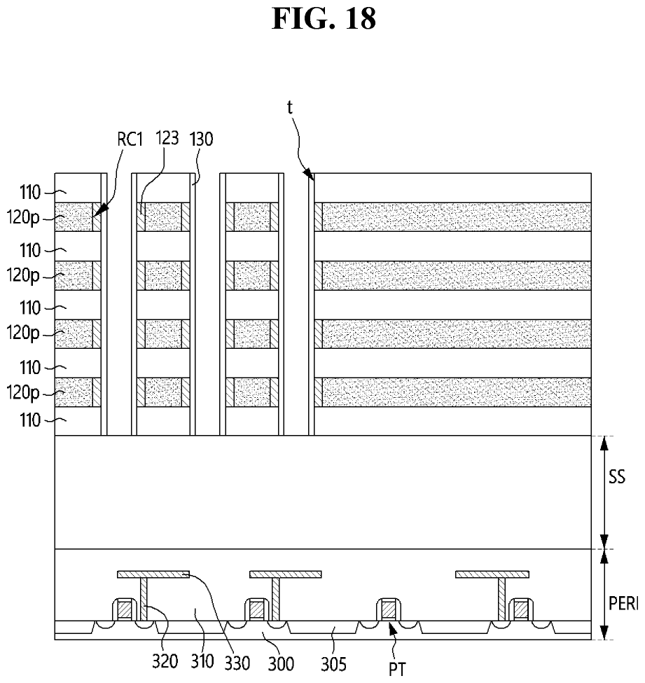

Referring to FIG. 18, the capacitor dielectric film 130 may be formed along the side walls of the trench t. The capacitor dielectric film 130 may be formed along the side walls of the mold insulating film 110 and the side walls of the second sub-film 123. The capacitor dielectric film 130 may not be formed along the bottom face of the trench t.

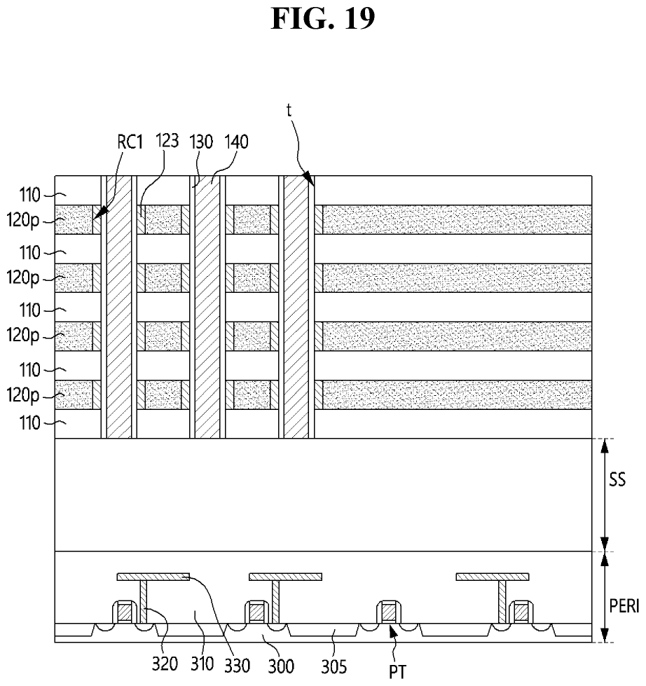

Referring to FIG. 19, a second electrode 140 may be formed. The second electrode 140 may fill between the capacitor dielectric films 130. That is, the second electrode 140 may fill the remaining trench t in which the capacitor dielectric film 130 is placed. The second electrode 140 may be connected to a capacitor contact (e.g., 260 of FIGS. 5 to 9) of the selection structure SS.

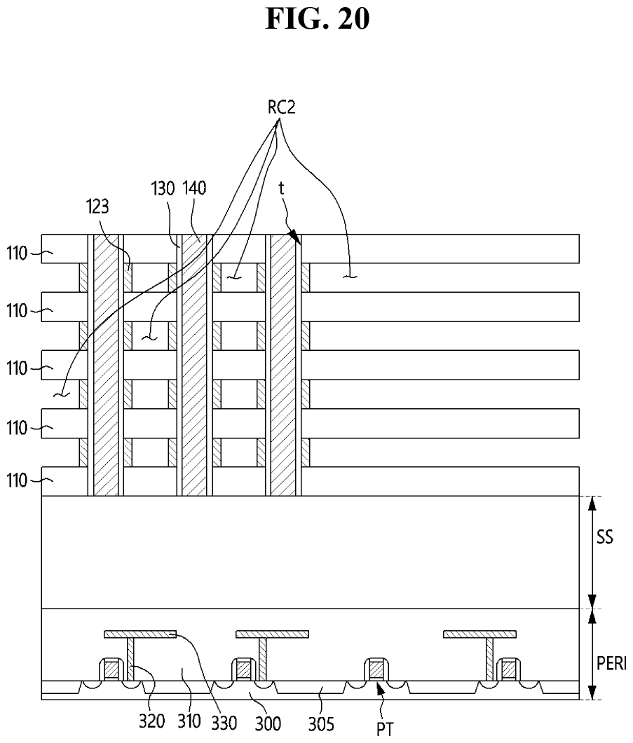

Referring to FIG. 20, the dummy first electrode 120p may be completely removed to form the second recess RC2.

Although not shown, an electrode cutting structure (e.g., 170 of FIG. 4) may be formed first. Before the electrode cutting structure 170 is formed, a cutting trench penetrating the mold insulating film 110 and the dummy first electrode 120p may be formed. The dummy first electrode 120p may be removed between the cutting trenches.

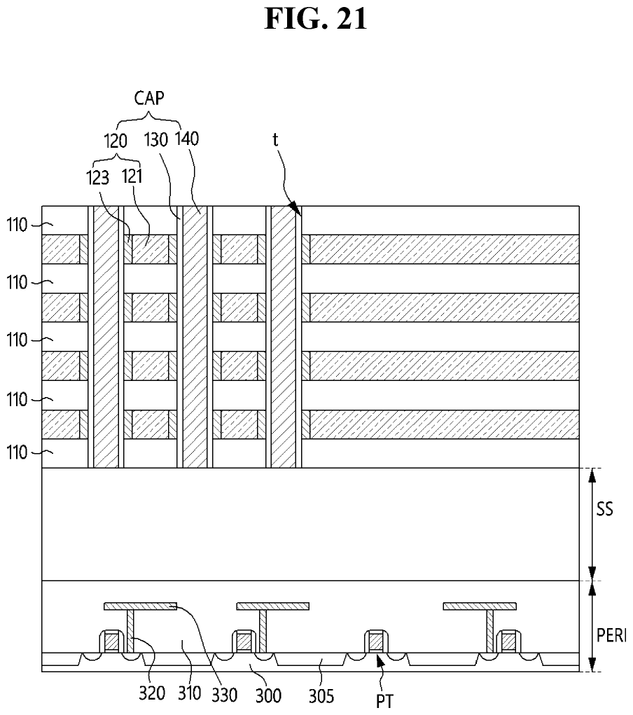

Referring to FIG. 21, the first sub-film 121 may be formed inside the second recess RC2. The first sub-film 121 may be formed of a material having a lower resistance than the second sub-film 123. The first sub-film 121 and the second sub-film 123 may constitute the first electrode 120. That is, the first electrode 120 may include a first sub-film 121 and a second sub-film 123.

Also, the first electrode 120, the capacitor dielectric film 130, and the second electrode 140 may constitute a capacitor CAP.

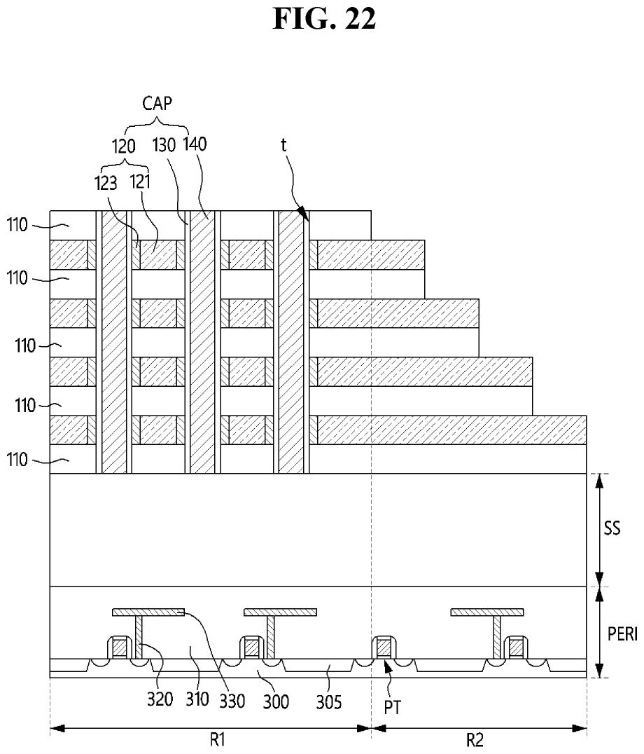

Referring to FIG. 22, a part of the mold insulating film 110 may be removed. The mold insulating film 110 may have a stepped shape or profile. Similarly, a part of first electrode 120 may be removed. The first electrode 120 may have a stepped shape or profile. A portion of the first electrode 120 may be exposed. The exposed region may be a region in which the first electrode contacts 160 to be formed later land.

The selection structure SS may include a first region R1 and a second region R2. The mold insulating film 110 and the first electrode 120 may have a stepped shape or profile on the second region R2. On the first region R1, the second electrode 140 may be connected to the selection structure SS.

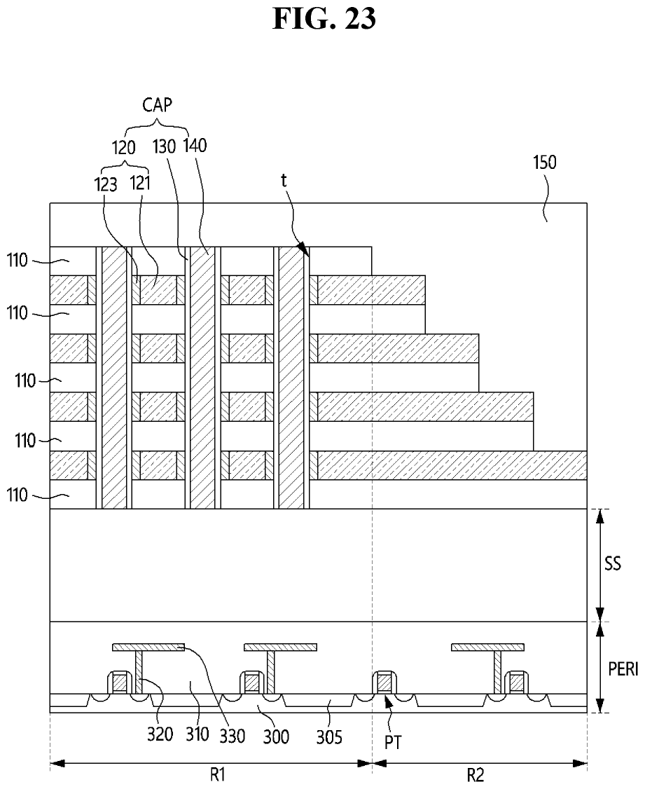

Referring to FIG. 23, the upper interlayer insulating film 150 that covers the mold insulating film 110, the first electrode 120, and the second electrode 140 may be formed.

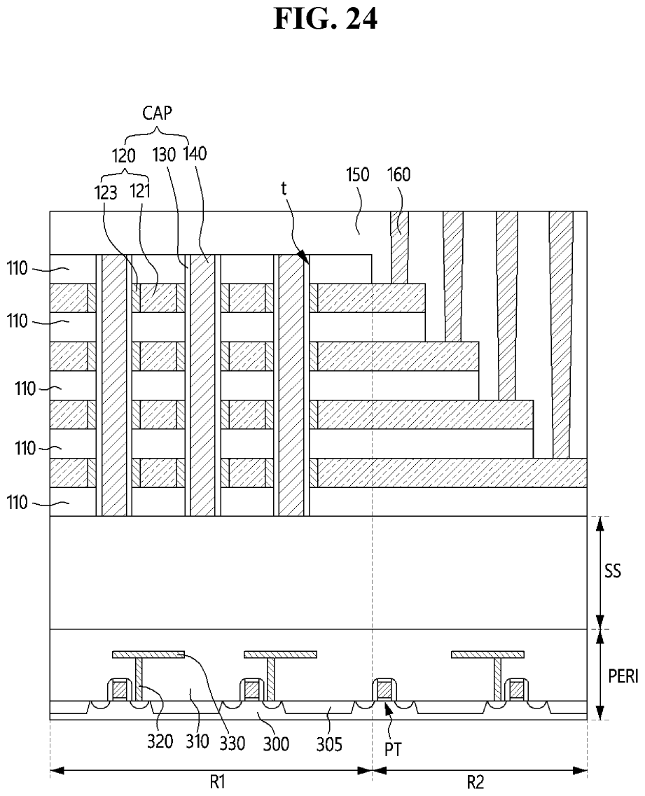

Referring to FIG. 24, first electrode contacts 160 connected to the exposed first electrodes 120 through the upper interlayer insulating film 150 may be formed.

In concluding the detailed description, those skilled in the art will appreciate that many variations and modifications may be made to the example embodiments without substantially departing from the principles of the present disclosure. Therefore, the disclosed example embodiments of the present disclosure are used in a generic and descriptive sense only and not for purposes of limitation.

What is claimed is:

1. A semiconductor memory device comprising:
a substrate;
a channel region on the substrate;
first and second source/drain regions electrically connected to the channel region;
a gate electrode that extends in a first direction and is on the channel region;
a conductive line that extends in a second direction intersecting the first direction and is electrically connected to the second source/drain region; and
a capacitor structure electrically connected to the first source/drain region on the substrate,
wherein the capacitor structure comprises:
a plurality of first electrodes stacked and spaced apart from each other in a third direction perpendicular to an upper surface of the substrate;
a plurality of trenches that extend into the plurality of first electrodes;
a capacitor dielectric film that extends along side walls of each of the plurality of trenches; and
a plurality of second electrodes in the plurality of trenches, respectively.

2. The semiconductor memory device of claim 1, wherein the capacitor dielectric film comprises a perovskite material or a fluorite material.

3. The semiconductor memory device of claim 1, wherein the capacitor dielectric film comprises zirconium oxide, hafnium-zirconium oxide, lead-zirconium oxide or sodium-niobium oxide.

4. The semiconductor memory device of claim 1, wherein the channel region comprises polysilicon or indium gallium zinc oxide (IGZO).

5. The semiconductor memory device of claim 1, wherein the gate electrode is in the substrate.

6. The semiconductor memory device of claim 1, wherein the channel region protrudes from the substrate in the third direction, and
wherein the gate electrode at least partially surrounds the channel region in a plan view.

7. The semiconductor memory device of claim 1, wherein the first source/drain region is electrically connected to one of the plurality of second electrodes.

8. The semiconductor memory device of claim 1, wherein each of the plurality of first electrodes comprises a first sub-film that is spaced apart from the capacitor dielectric film, and a second sub-film that is in contact with the capacitor dielectric film.

9. The semiconductor memory device of claim 1, wherein each of the plurality of trenches has a circular, elliptical or rectangular shape in a plan view.

10. The semiconductor memory device of claim 1, wherein the plurality of first electrodes each extend in the first direction.

11. A semiconductor memory device comprising:
a substrate including a first region and a second region;
a plurality of transistors that are on the first region of the substrate, wherein ones of the plurality of transistors each include a gate electrode, a channel region, and a source/drain region; and
a capacitor structure electrically connected to the source/drain region of each of the ones of the plurality of transistors,
wherein the capacitor structure comprises:
a plurality of first electrodes that extend in a first direction, are stacked and spaced apart from each other in a third direction perpendicular to an upper surface of the substrate, and have a stepped profile on the second region of the substrate;
a plurality of second electrodes that extend in a second direction intersecting the first direction on the first region of the substrate, extend into the plurality of first electrodes, and are electrically connected to the source/drain region of each of the ones of the plurality of transistors, respectively; and
a capacitor dielectric film between respective ones of the plurality of first electrodes and respective ones of the plurality of second electrodes.

12. The semiconductor memory device of claim 11, wherein the gate electrode extends in the first direction.

13. The semiconductor memory device of claim 11, wherein at least one of the plurality of transistors comprises a buried transistor (BCAT), a planar transistor, a fin-shaped transistor (FinFET) or a vertical channel transistor (VCT).

14. The semiconductor memory device of claim 11, wherein the channel region comprises polysilicon or indium gallium zinc oxide (IGZO).

15. The semiconductor memory device of claim 11, wherein the capacitor dielectric film comprises a perovskite material or a fluorite material.

16. The semiconductor memory device of claim 11, wherein each of the plurality of second electrodes has an elliptical shape in a plan view, and
wherein the elliptical shape extends longitudinally in the second direction.

17. The semiconductor memory device of claim 11, further comprising:
an electrode cutting structure that extends in the first direction, wherein the electrode cutting structure extends into the plurality of first electrodes between respective ones of the plurality of second electrodes.

18. A semiconductor memory device comprising:
a peripheral circuit structure including a peripheral circuit element; and
a cell structure that includes a plurality of memory cells and overlaps the peripheral circuit structure in a first direction,
wherein the peripheral circuit element is configured to control an operation of at least one of the plurality of memory cells,
wherein each of the plurality of memory cells includes a transistor and at least two capacitors electrically connected to the transistor,
wherein each of the at least two capacitors comprises:
a first electrode extending in a second direction that intersects the first direction;
a second electrode that extends into the first electrode and is electrically connected to a source/drain region of the transistor; and
a capacitor dielectric film including a ferroelectric material between the first electrode and the second electrode.

19. The semiconductor memory device of claim 18, wherein the transistor comprises a buried transistor (BCAT), a planar transistor, a fin-shaped transistor (FinFET) or a vertical channel transistor (VCT).

20. The semiconductor memory device of claim 18, wherein a channel region of the transistor comprises polysilicon or indium gallium zinc oxide (IGZO).
